(19) United States
(12) Patent Application Publication
(10) Pub. No.: US 2012/0161836 A1
(43) Pub. Date: Jun. 28, 2012

(54) CHARGE PUMP DEVICE AND METHOD FOR REGULATING THE SAME

(75) Inventors: XIAO-MING DUAN, Hsinchu County (TW); RONALD CHANG, Hsinchu County (TW)

(73) Assignee: HANERGY TECHNOLOGIES, INC., Hsinchu County (TW)

(21) Appl. No.: 13/298,870

(22) Filed: Nov. 17, 2011

(30) Foreign Application Priority Data
Dec. 24, 2010 (TW) 099145952

(51) Int. Cl. H03L 7/097

(52) U.S. Cl. 327/157

(57) ABSTRACT

A charge pump device is provided. The charge pump device includes a clamping unit providing a first pulse and a second pulse having a phase identical to that of the first pulse, wherein each of the first and the second pulses has an amplitude; a charge pump unit outputting a first voltage in response to the first pulse and the second pulse; and a feedback unit outputting a second voltage in response to the first voltage, wherein the clamping unit adjusts the amplitude of one of the first pulse and the second pulse in response to the second voltage to regulate the first voltage.

### CROSS-REFERENCE TO RELATED APPLICATION AND CLAIM OF PRIORITY

The application claims the benefit of Taiwan Patent Application No. 099145952, filed on Dec. 24, 2010, in the Taiwan Intellectual Property Office, the disclosures of which are incorporated herein in their entirety by reference.

### FIELD OF THE INVENTION

The present invention relates to a charge pump device and a method for regulating the same, and more particularly to a charge pump device for adjusting the amplitude of the pulse and a method for regulating the same.

### BACKGROUND OF THE INVENTION

The electronic product has become very popular in recent years and has more and more functions. Different functions need to be achieved by different hardware circuits, and different hardware circuits need different voltage supplies which generally are different DC voltages. Hence, the DC/DC converter is required for converting a DC voltage into another DC voltage.

Generally, the DC/DC converter can be divided into three types: the linear regulator, the switching regulator and the charge pump.

The linear regulator has a simple circuit structure. Since switches are not used in the linear regulator, there is no noise interference resulting from switches being turned on or off. However, the linear regulator only can perform the function of step-down. Besides, if a large step-down occurs, the converting efficiency of the linear regulator will be affected.

The switching regulator basically includes the switch, inductor and capacitor. The switching regulator has a high converting efficiency, but a larger noise interference resulting from switches being turned on or off. However, since the inductor has a larger volume, generally it is disposed outside the chip. That is, only the controller, switch and capacitor, without the inductor, are disposed in the chip. The step-up or step-down circuit can be formed by different combinations of the switch, inductor and capacitor so as to provide different DC voltages.

Compared to the switching regulator, the charge pump does not need the inductor so that it can be disposed in the chip. However, without the feedback circuit, the output voltage of the charge pump is easily affected by the load thereof. Therefore, the output voltage of the charge pump is unstable and unprecise.

Please refer to FIG. 1(a), which shows a conventional charge pump device. The charge pump device 10 includes a charge pump unit 11, a feedback unit 12, a pulse width modulation generator 13 and a load 14. The charge pump unit 11 includes a DC voltage source 110, a p-type transistor 111, an n-type transistor 112, a diode D₁, a diode D₂, a capacitor C₁ and a capacitor C₂.

The DC voltage source 110 provides a voltage Vᵢₙ₁, and the pulse width modulation generator 13 provides a pulse CLK1 having a duty ratio of 50%. The pulse CLK1 controls the turn-on or turn-off of the p-type transistor 111 and the n-type transistor 112 to charge the capacitor C₁, thereby enabling the charge pump device 10 to provide a voltage Vₒ₁ to the load 14.

When the voltage Vₒ₁ is changed, the feedback unit 12 generates a first signal S₁ in response to the voltage Vₒ₁, and the pulse width modulation generator 13 generates a pulse CLK2 in response to the first signal S₁. The duty ratio of the pulse CLK1 is adjusted by the pulse width modulation generator 13 so that the pulse CLK1 is changed into the pulse CLK2 to regulate the voltage Vₒ₁.

Please refer to FIG. 1(b), which shows another conventional charge pump device. The charge pump device 20 includes a charge pump unit 21, a feedback unit 22, a pulse generator 23 and a load 24. The charge pump unit 21 includes a DC voltage source 210, a DC current source 211, a diode D₁, a diode D₂, a capacitor C₁, a capacitor C₂, a switch SW1 and a switch SW2.

The DC voltage source 210 provides a voltage Vᵢₙ₂, the DC current source 211 provides a current i1, and the pulse generator 23 provides a pulse CLK3 having a duty ratio of 50%. The pulse CLK3 controls the turn-on or turn-off of the switches SW1, SW2 to charge the capacitor C₁, thereby enabling the charge pump device 20 to provide a voltage Vₒ₁ to the load 24.

When the voltage Vₒ₁ is changed, the feedback unit 22 generates a second signal S₂ in response to the voltage Vₒ₁. The current i1 is appropriately adjusted by the DC current source 211 according to the second signal S₂ so as to regulate the voltage Vₒ₁.

The above-mentioned way of adjusting the duty ratio of the pulse by using the pulse width modulation generator requires a more complicated circuit. Therefore, in order to overcome the drawbacks in the prior art, a charge pump device and a method for regulating the same are provided in the present invention. The particular design in the present invention not only solves the problems described above, but also is easy to be implemented. Thus, the present invention has the utility for the industry.

### SUMMARY OF THE INVENTION

The present invention provides a charge pump device and a method for regulating the same, which has a simple circuit structure and can achieve the effect of regulating the voltage rapidly.

In accordance with an aspect of the present invention, a charge pump device is provided. The charge pump device includes a clamping unit providing a first pulse and a second pulse having a phase identical to that of the first pulse, wherein each of the first and the second pulses has an amplitude; a charge pump unit outputting a first voltage in response to the first pulse and the second pulse; and a feedback unit outputting a second voltage in response to the first voltage, wherein the clamping unit adjusts the amplitude of one of the first pulse and the second pulse in response to the second voltage to regulate the first voltage.

In accordance with another aspect of the present invention, a charge pump device is provided. The charge pump device includes a clamping unit providing a first pulse and a second pulse having a phase identical to that of the first pulse, wherein each of the first and the second pulses has an amplitude; a charge pump unit outputting a first voltage in response to the first pulse and the second pulse; and a feedback unit outputting a first current in response to the first voltage, wherein the clamping unit adjusts the amplitude of one of the first pulse and the second pulse in response to the first current to regulate the first voltage.

In accordance with a further aspect of the present invention, a charge pump device is provided. The charge pump device includes a charge pump unit outputting a voltage in response to a first pulse and a second pulse, wherein each of the first and the second pulses has an amplitude; and an adjusting unit adjusting the amplitude of one of the first pulse and the second pulse to regulate the voltage when the voltage changes.

In accordance with further another aspect of the present invention, a method for regulating a charge pump device is provided. The method includes steps of providing a first pulse and a second pulse, wherein each of the first and the second pulses has an amplitude; outputting a first voltage in response to the first pulse and the second pulse; and adjusting the amplitude of one of the first pulse and the second pulse to regulate the first voltage when the first voltage changes.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1(a) shows a conventional charge pump device;

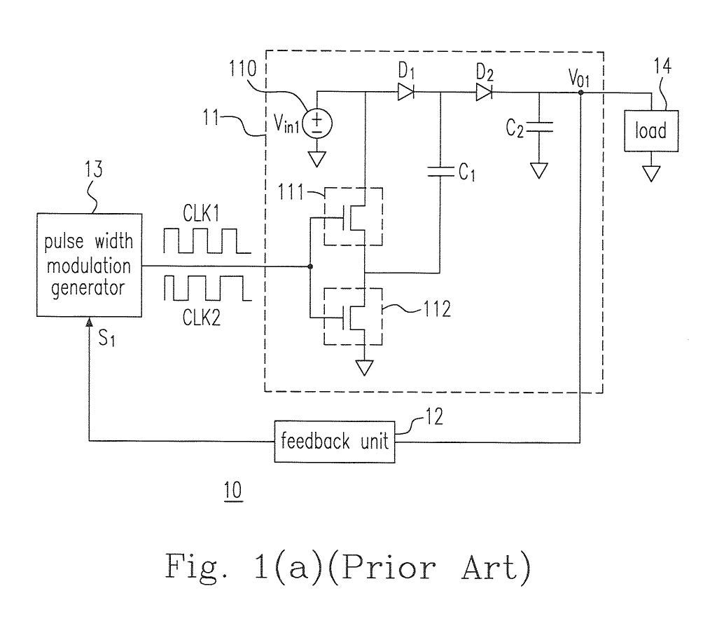

FIG. 1(b) shows another conventional charge pump device;

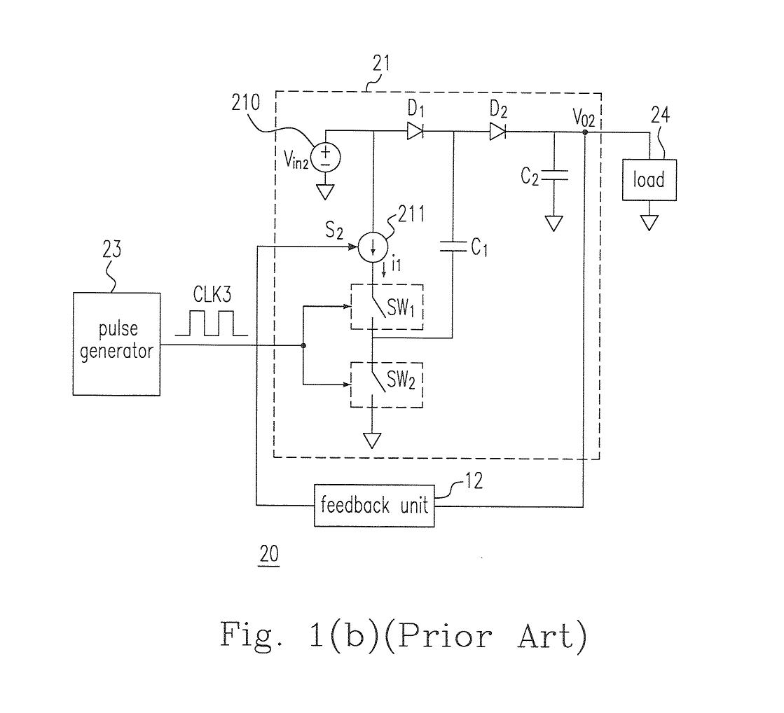

FIG. 2(a) shows a charge pump device according to a first embodiment of the present invention;

FIG. 2(b) shows a clamping circuit according to the first embodiment of the present invention;

FIG. 2(c) shows the waveforms according to the first embodiment of the present invention;

FIG. 2(d) shows a clamping circuit according to a second embodiment of the present invention;

FIG. 2(e) shows the waveforms according to the second embodiment of the present invention;

FIG. 3(a) shows a charge pump device according to a third embodiment of the present invention;

FIG. 3(b) shows a clamping circuit according to the third embodiment of the present invention;

FIG. 3(c) shows the waveforms according to the third embodiment of the present invention;

FIG. 3(d) shows a clamping circuit according to a fourth embodiment of the present invention;

FIG. 3(e) shows the waveforms according to the fourth embodiment of the present invention;

FIG. 4(a) shows a charge pump device according to a fifth embodiment of the present invention;

FIG. 4(b) shows a charge pump device according to a sixth embodiment of the present invention;

FIG. 5 shows a charge pump device according to a seventh embodiment of the present invention; and

FIG. 6 is a flowchart of a method for regulating a charge pump device according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

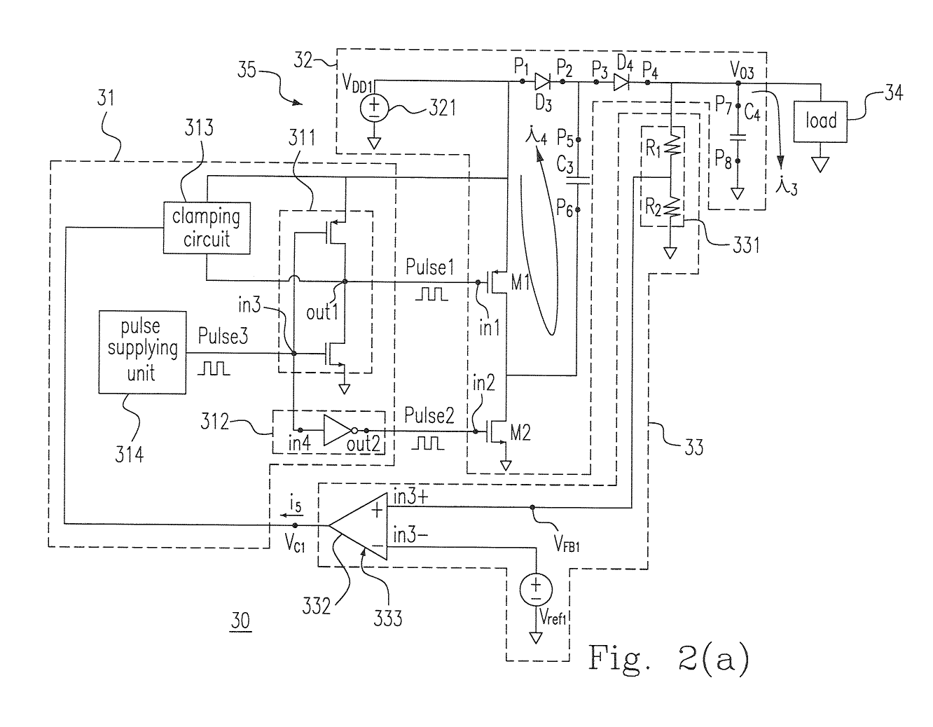

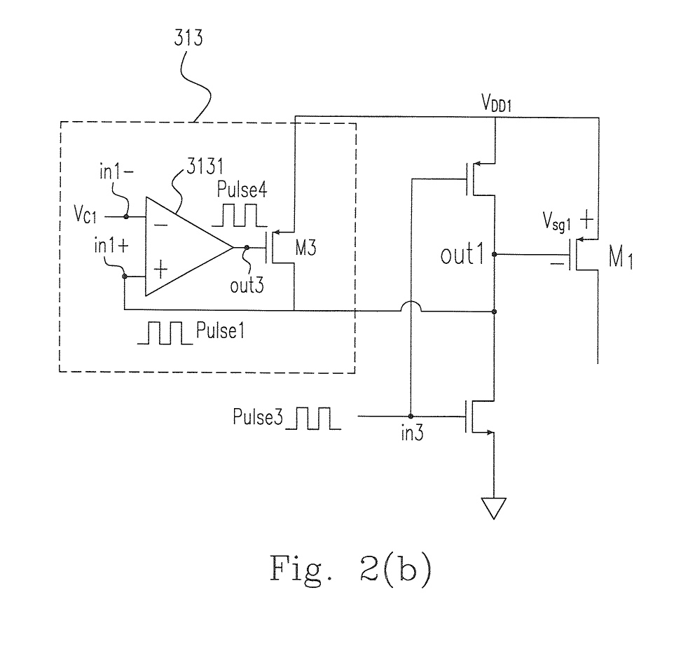

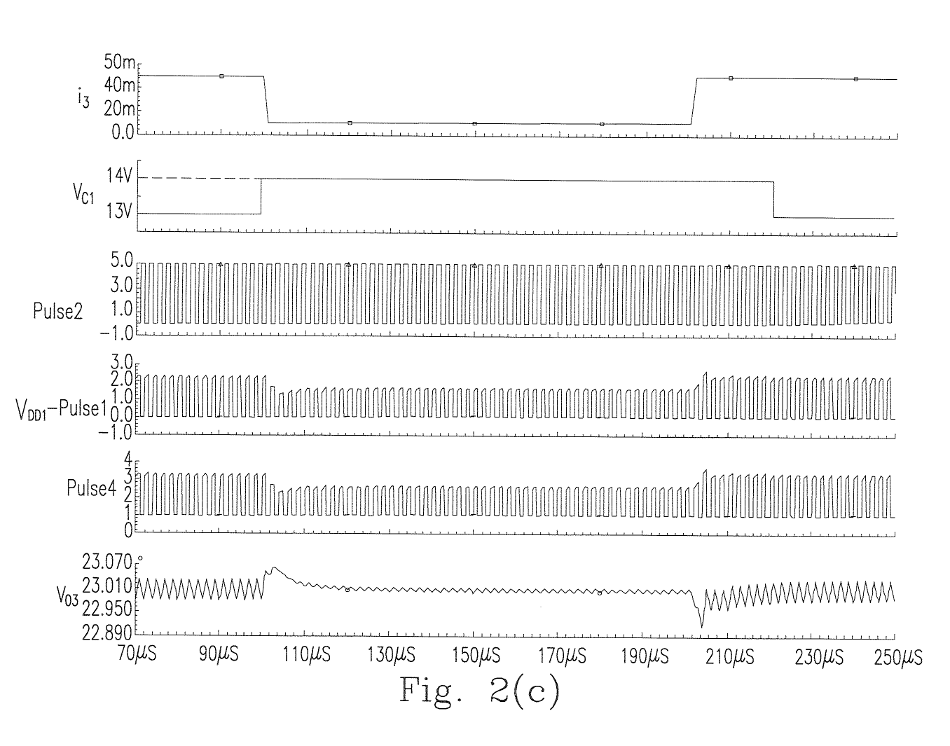

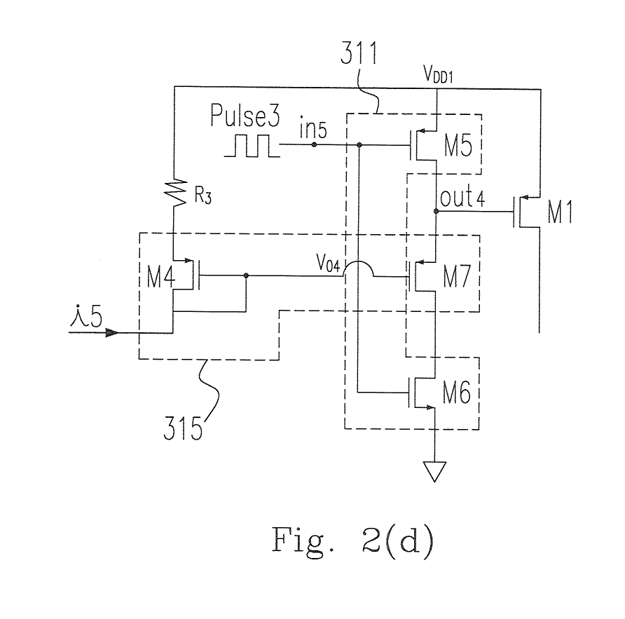

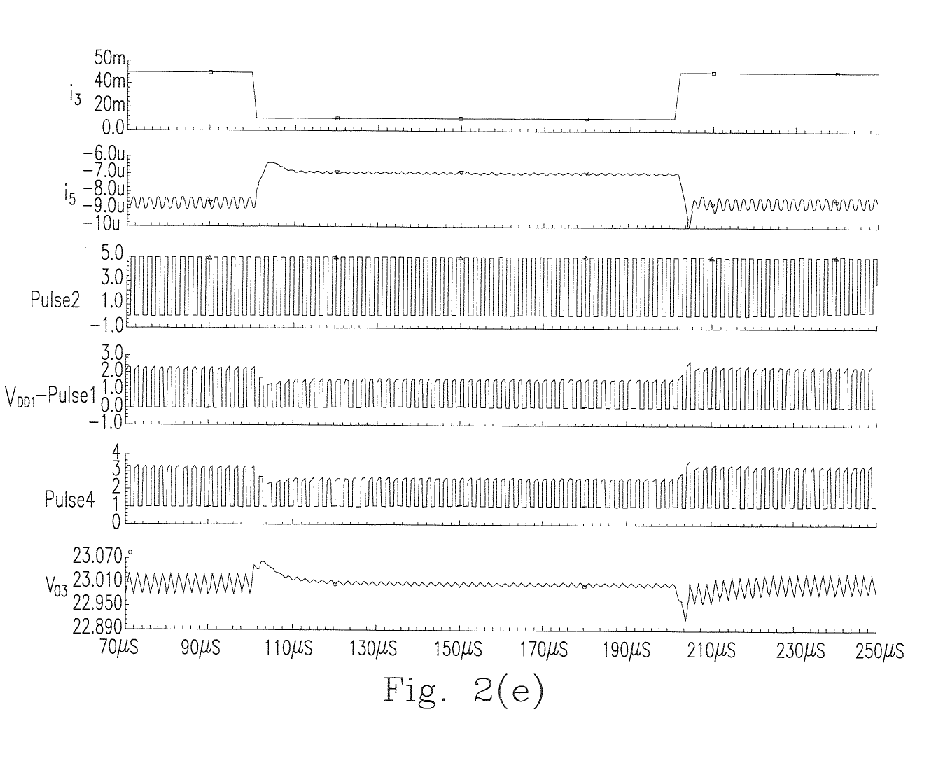

Please refer to FIG. 2(a), which shows a charge pump device according to a first embodiment of the present invention. The charge pump device 30 includes a clamping unit 31, a charge pump unit 32 and a feedback unit 33. The clamping unit 31 provides a first pulse Pulse1 and a second pulse Pulse2 having a phase identical to that of the first pulse Pulse1. The charge pump unit 32 has a first input terminal in1 receiving the first pulse Pulse1, and a second input terminal in2 receiving the second pulse Pulse2. Besides, the charge pump unit 32 outputs a first voltage Vₒ₃ in response to the first pulse Pulse1 and the second pulse Pulse2. The feedback unit 33 outputs a second voltage V_{c1} in response to the first voltage Vₒ₃. The clamping unit 31 adjusts the amplitude of the first pulse Pulse1 or the second pulse Pulse2 in response to the second voltage V_{c1} to regulate the first voltage Vₒ₃.

The charge pump unit 32 is a positive charge pump unit 35 including a DC voltage source 321, a first diode D₃, a second diode D₄, a first p-type transistor M1, a first n-type transistor M2, a first capacitor C₃ and a second capacitor C₄. The feedback unit 33 includes a sensing unit 331 and an operational amplifying unit 332.

The DC voltage source 321 provides a third voltage V_{DD1}. The first diode D₃ has a first terminal P₁ and a second terminal P₂, wherein the first terminal P₁ receives the third voltage V_{DD1}. The second diode D₄ has a third terminal P₃ and a fourth terminal P₄, wherein the third terminal P₃ is connected to the second terminal P₂. The source of the first p-type transistor M1 receives the third voltage V_{DD1}, and the gate thereof serves as the first input terminal in1. The source of the first n-type transistor M2 is connected to the ground, the gate thereof serves as the second input terminal in2, and the drain thereof is connected to the drain of the first p-type transistor M1. The first capacitor C₃ has a fifth terminal P₅ and a six terminal P₆, wherein the fifth terminal P₅ is connected to the third terminal P₃, and the sixth terminal P₆ is connected to the drain of the first p-type transistor M1. The second capacitor C₄ has a seventh terminal P₇ and an eighth terminal P₈, wherein the seventh terminal P₇ is connected to the fourth terminal P₄ and the load 34 of the charge pump device 30, and the eighth terminal P₈ is connected to the ground. A current i₃ flows through the load 34. When the charge pump device 30 is in a normal condition, the current i₃ is a stable DC current.

The sensing unit 331 includes a voltage divider. The voltage divider includes resistors R₁, R₂, and outputs a fourth voltage V_{FB1} by dividing the first voltage Vₒ₃. The operational amplifying unit 332 receives the fourth voltage V_{FB1} and a reference voltage V_{ref1}, and outputs the second voltage V_{c1} according to the difference between the fourth voltage V_{FB1} and the reference voltage V_{ref1}. The fourth voltage V_{FB1} is input to the positive input terminal in3+ of the operation amplifying unit 332, and the reference voltage V_{ref1} is input to the negative input terminal in3− thereof.

The clamping unit 31 includes a pulse supplying unit 314, a first inverting unit 311, a second inverting unit 312 and a clamping circuit 313. The pulse supplying unit 314 provides a third pulse Pulse3. The first inverting unit 311 has a third input terminal in3 and a first output terminal out1, wherein the third input terminal in3 receives the third pulse Pulse3, and the first output terminal out1 is connected to the gate of the first p-type transistor M1. Besides, the first inverting unit 311 outputs the first pulse Pulse1 in response to the third pulse Pulse3. The second inverting unit 312 has a fourth input terminal in4 and a second output terminal out2, wherein the fourth input terminal in4 receives the third pulse Pulse3, and the second output terminal out2 is connected to the gate of the first n-type transistor M2. Moreover, the second inverting unit 312 outputs the second pulse Pulse2 in response to the third pulse Pulse3.

Please refer to FIG. 2(b), which shows a clamping circuit according to the first embodiment of the present invention. The clamping circuit 313 includes an amplifier 3131 and a second p-type transistor M3. The amplifier 3131 has a positive input terminal in1+, a negative input terminal in1− and a third output terminal out3. The positive input terminal in1+ of the amplifier 3131 receives the first pulse Pulse1, and the negative input terminal in1− thereof receives the second voltage V_{c1}. Besides, the amplifier 3131 outputs a fourth pulse Pulse4 in response to the second voltage V_{c1} and the first pulse Pulse1. The gate of the second p-type transistor M3 is connected to the third output terminal out3 and receives the fourth pulse Pulse4, and the drain thereof is connected to the positive input terminal in1+ of the amplifier 3131 and the gate of the first p-type transistor M1. Moreover, the second p-type transistor M3 adjusts the amplitude of the first pulse Pulse1 in response to the fourth pulse Pulse4.

Please refer to FIGS. 2(a) and 2(b) simultaneously. When the first voltage Vₒ₃ is increased, since the fourth voltage V_{FB1} is a divided voltage of the first voltage Vₒ₃, the fourth voltage V_{FB1} and the second voltage V_{c1} output by the operational amplifying unit 332 are changed accordingly, which enables the voltage input to the negative input terminal in1− of the amplifier 3131 in the clamping circuit 313 to be changed accordingly.

When the second p-type transistor M3 is turned on, the voltage at the drain of the second p-type transistor M3 is pulled up toward the third voltage V_{DD1}. Hence, the voltage input to the positive input terminal in1+ of the amplifier 3131 is increased, until approaching the voltage at the negative input terminal in1− thereof (i.e. the second voltage V_{c1}). The voltage output from the third output terminal out3 of the amplifier 3131 can keep the second p-type transistor M3 in a weak turn-on status. When the voltage at the drain of the second p-type transistor M3 is pulled up toward the third voltage V_{DD1}, the source-to-gate voltage V_{sg1} of the first p-type transistor M1 is decreased. This can achieve the effect of clamping the voltage. Therefore, the current i4 for charging the first capacitor C3 is restrained so that the first voltage Vₒ₃ is decreased. For the first pulse Pulse1, the magnitude of the amplitude thereof is increased toward the third voltage V_{DD1} so that the amplitude of the first pulse Pulse1 is adjusted. Similarly, when the first voltage Vₒ₃ is decreased, according to the principle similar to that described above, the effect of increasing the first voltage Vₒ₃ can be achieved. That is, the charge pump device 30 according to the first embodiment of the present invention can achieve the effect of regulating the first voltage Vₒ₃.

Please refer to FIG. 2(c), which shows the waveforms according to the first embodiment of the present invention. In the waveform diagram of the current i3, the transverse axle represents the time whose unit is the microsecond, and the vertical axle represents the current whose unit is the mill-ampere. In the waveform diagram of the first voltage Vₒ₃, the transverse axle represents the time whose unit is the microsecond, and the vertical axle represents the voltage whose unit is the volt. In the waveform diagram of the second voltage V_{c1}, the transverse axle represents the time whose unit is the microsecond, and the vertical axle represents the voltage whose unit is the volt. In the waveform diagram of the second pulse Pulse2, the transverse axle represents the time whose unit is the microsecond, and the vertical axle represents the voltage whose unit is the volt. In the waveform diagram of the fourth pulse Pulse4, the transverse axle represents the time whose unit is the microsecond, and the vertical axle represents the voltage whose unit is the volt. In the waveform diagram of the difference between the third voltage V_{DD1} and the first pulse Pulse1, the transverse axle represents the time whose unit is the microsecond, and the vertical axle represents the voltage whose unit is the volt.

Please refer to FIGS. 2(a), 2(b) and 2(c) simultaneously. When the current i3 is suddenly changed from 40 mA to about 8 mA, the first voltage Vₒ₃ is also suddenly changed from about 23.01 V to 23.07 V, and the second voltage V_{c1} is changed from 13 V to 14 V. At this time, the amplitude of the first pulse Pulse1 is increased due to the adjustment by the clamping circuit 313, which enables the amplitude of the fourth pulse Pulse4 to be reduced so that the amplitude formed by the difference between the third voltage V_{DD1} and the first pulse Pulse1 is reduced accordingly. This represents that the voltage V_{sg1} for driving the first p-type transistor M1 is also reduced accordingly. Hence, the first voltage Vₒ₃ returns to 23.01 V soon.

Please refer to FIG. 2(d), which shows a clamping circuit according to a second embodiment of the present invention. The second embodiment of the present invention is similar to the first embodiment of the present invention, except the structure of the clamping circuit. The clamping circuit 313 in the first embodiment of the present invention can be replaced with the clamping circuit 315 in the second embodiment of the present invention. In an embodiment, the operational amplifying unit 332 can be regarded as a trans-conductance unit 333. The trans-conductance unit 333 outputs a first current i5 in response to the fourth voltage V_{FB1}, as shown in FIG. 2(a).

In FIG. 2(d), the first inverting unit 311 includes a second p-type transistor M5 and a second n-type transistor M6. The first inverting unit 311 has a third input terminal in5 and a first output terminal out4. The third input terminal in5 receives the third pulse Pulse3, and the first inverting unit 311 outputs the first pulse Pulse1 in response to the third pulse Pulse3. The first output terminal out4 is connected to the gate of the first p-type transistor M1.

The clamping circuit 315 includes a third p-type transistor M4 and a fourth p-type transistor M7. The gate of the third p-type transistor M4 is connected to the drain thereof. The third p-type transistor M4 outputs a third voltage V_{O4} in response to the first current i5. The clamping circuit 315 further includes a transistor R₃ for converting the current i5 into the third voltage V_{O4}. The gate of the fourth p-type transistor M7 is connected to the gate of the third p-type transistor M4, the drain of the fourth p-type transistor M7 is connected to the drain of the second n-type transistor M6, and the source of the fourth p-type transistor M7 is connected to the drain of the second p-type transistor M5 and the gate of the first p-type transistor M1. The fourth p-type transistor M7 adjusts the amplitude of the first pulse Pulse1 in response to the third voltage Vₒ₄ and the first pulse Pulse1.

Please refer to FIG. 2(e), which shows the waveforms according to the second embodiment of the present invention. In the waveform diagram of the currents i5, the transverse axle represents the time whose unit is the microsecond, and the vertical axle represents the current whose unit is the microampere. In the waveform diagram of the currents i3, the transverse axle represents the time whose unit is the microsecond, and the vertical axle represents the current whose unit is the milli-ampere. In the waveform diagram of the first voltage Vₒ₃, the transverse axle represents the time whose unit is the microsecond, and the vertical axle represents the voltage whose unit is the volt. In the waveform diagram of the second pulse Pulse2, the transverse axle represents the time whose unit is the microsecond, and the vertical axle represents the voltage whose unit is the volt. In the waveform diagram of the fourth pulse Pulse4, the transverse axle represents the time whose unit is the microsecond, and the vertical axle represents the voltage whose unit is the volt. In the waveform diagram of the difference between the third voltage V_{DD1} and the first pulse Pulse1, the transverse axle represents the time whose unit is the microsecond, and the vertical axle represents the voltage whose unit is the volt.

Please refer to FIGS. 2(a), 2(d) and 2(e) simultaneously. When the current i3 is suddenly changed from 40 mA to about 8 mA, the first voltage Vₒ₃ is also suddenly changed from about 23.01 V to 23.07 V, and the current i5 is changed from −9 uA to −7 uA. At this time, the amplitude of the fourth pulse Pulse4 is reduced due to the adjustment by the clamping circuit 315, the amplitude of the first pulse Pulse1 is increased due to the adjustment by the clamping circuit 315, and the amplitude formed by the difference between the third voltage V_{DD1} and the first pulse Pulse1 is reduced accordingly. This represents that the voltage V_{sg1} for driving the first p-type transistor M1 is also reduced accordingly. Hence, the first voltage Vₒ₃ returns to 23.01 V soon.

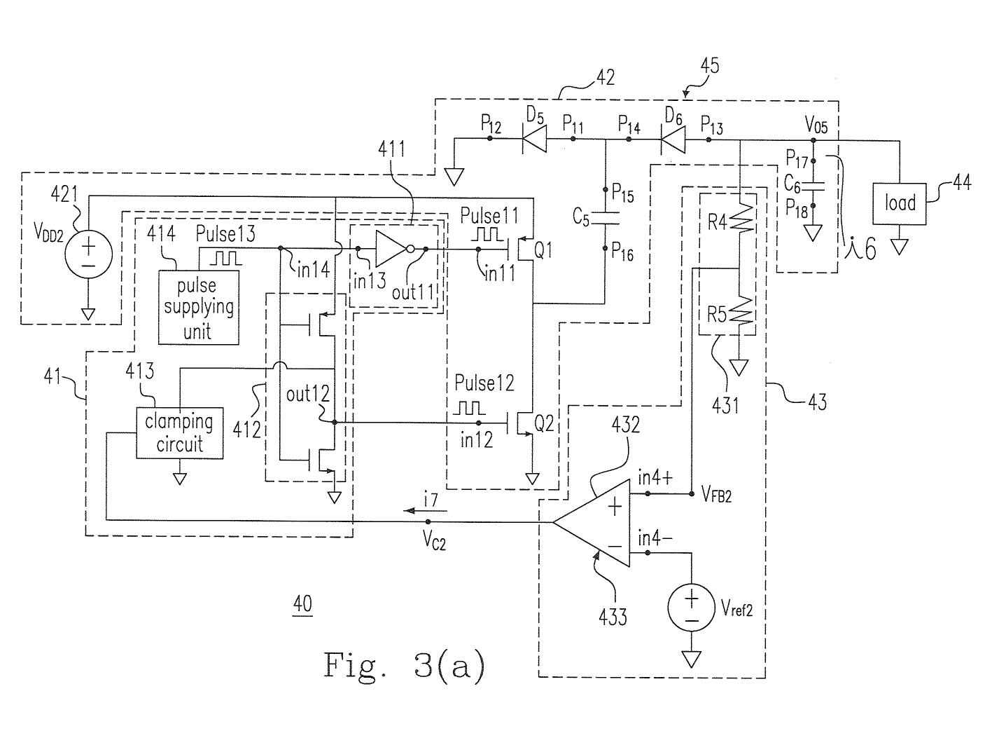

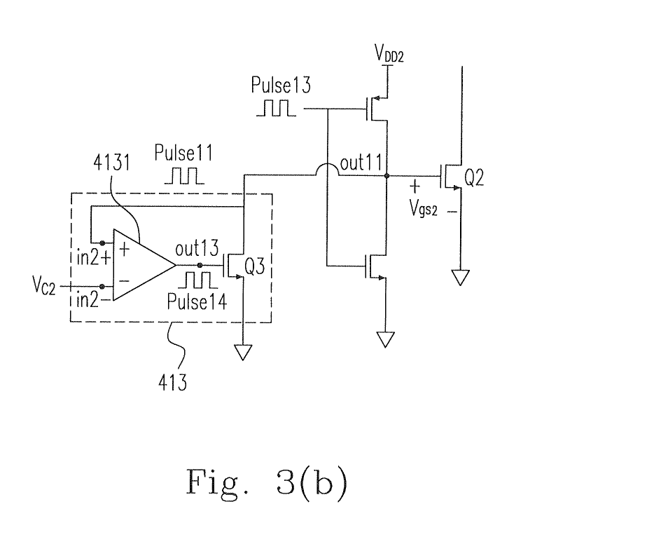

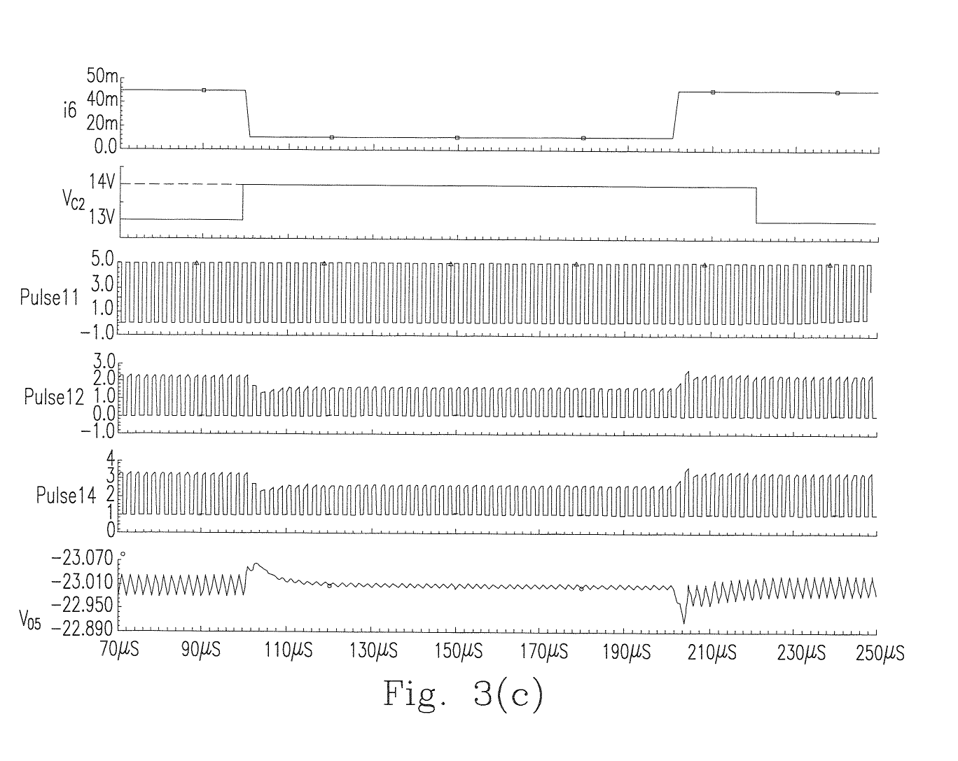

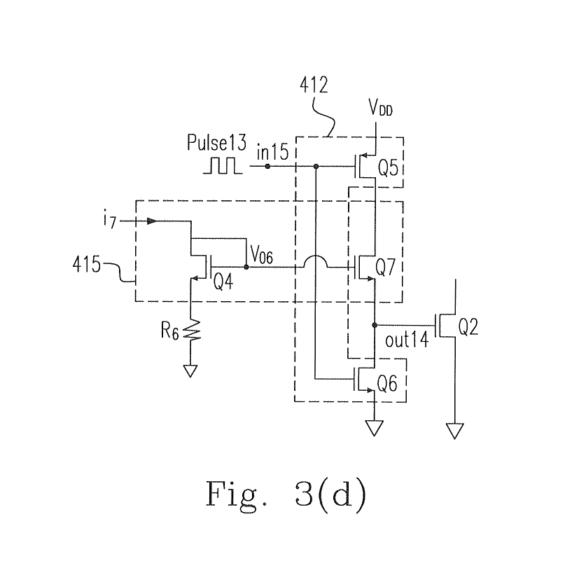

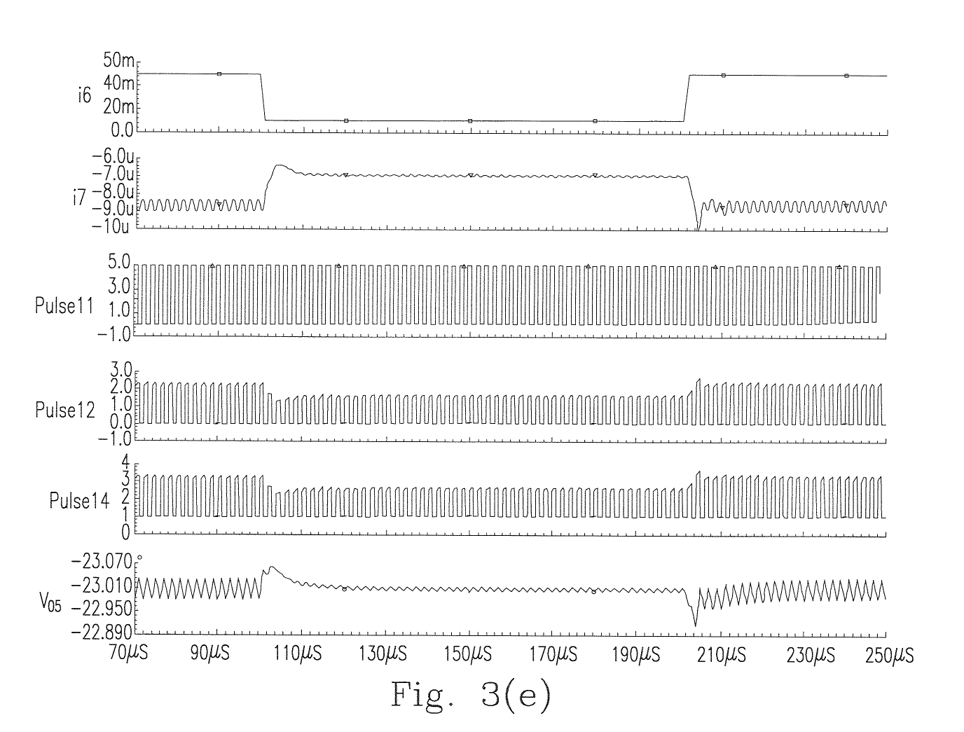

Please refer to FIG. 3(a), which shows a charge pump device according to a third embodiment of the present invention. The charge pump device 40 includes a clamping unit 41, a charge pump unit 42 and a feedback unit 43. The clamping unit 41 provides a first pulse Pulse11 and a second pulse Pulse12 having a phase identical to that of the first pulse Pulse11. The charge pump unit 42 has a first input terminal in11 receiving the first pulse Pulse11, and a second input terminal in12 receiving the second pulse Pulse12. Besides, the charge pump unit 42 outputs a first voltage Vₒ₅ in response to the first pulse Pulse11 and the second pulse Pulse12. The feedback unit 43 outputs a second voltage V_{c2} in response to the first voltage Vₒ₅. The clamping unit 41 adjusts the amplitude of the first pulse Pulse11 or the second pulse Pulse12 in response to the second voltage V_{c2} to regulate the first voltage Vₒ₅.

The charge pump unit 42 is a negative charge pump unit 45 including a DC voltage source 421, a first diode D₅, a second diode D₆, a first p-type transistor Q1, a first n-type transistor Q2, a first capacitor C₅ and a second capacitor C₆. The feedback unit 43 includes a sensing unit 431 and an operational amplifying unit 432.

The DC voltage source 421 provides a third voltage V_{DD2}. The first diode D₅ has a first terminal P₁₁ and a second terminal P₁₂, wherein the second terminal P₁₂ is connected to the ground. The second diode D₆ has a third terminal P₁₃ and a fourth terminal P₁₄, wherein the fourth terminal P₁₄ is connected to the first terminal P₁₁. The source of the first p-type transistor Q1 receives the third voltage V_{DD2}, and the gate thereof serves as the first input terminal in11. The source of the first n-type transistor Q2 is connected to the ground, the gate thereof serves as the second input terminal in12, and the drain thereof is connected to the drain of the first p-type transistor Q1. The first capacitor C₅ has a fifth terminal P₁₅ and a six terminal P₁₆, wherein the fifth terminal P₁₅ is connected to the fourth terminal P₁₄, and the sixth terminal P₁₆ is connected to the drain of the first p-type transistor Q1. The second capacitor C₆ has a seventh terminal P₁₇ and an eighth terminal P₁₈, wherein the seventh terminal P₁₇ is connected to the third terminal P₁₃ and the load 44 of the charge pump device 40, and the eighth terminal P₁₈ is connected to the ground. A current i₆ flows through the load 44. When the charge pump device 40 is in a normal condition, the current i₆ is a stable DC current.

The sensing unit 431 includes a voltage divider. The voltage divider includes resistors R₄, R₅, and outputs a fourth voltage V_{FB2} by dividing the first voltage Vₒ₅. The operational amplifying unit 432 receives the fourth voltage V_{FB2} and a reference voltage V_{ref2}, and outputs the second voltage V_{c2} according to the difference between the fourth voltage V_{FB2} and the reference voltage V_{ref2}. The fourth voltage V_{FB2} is input to the positive input terminal in4+ of the operation amplifying unit 432, and the reference voltage V_{ref2} is input to the negative input terminal in4− thereof.

The clamping unit 41 includes a pulse supplying unit 414, a first inverting unit 411, a second inverting unit 412 and a clamping circuit 413. The pulse supplying unit 414 provides a third pulse Pulse13. The first inverting unit 411 has a third input terminal in 13 and a first output terminal out11, wherein the third input terminal in13 receives the third pulse Pulse13, and the first output terminal out11 is connected to the gate of the first p-type transistor Q1. Besides, the first inverting unit 411 outputs the first pulse Pulse11 in response to the third pulse Pulse13. The second inverting unit 412 has a fourth input terminal in14 and a second output terminal out 12, wherein the fourth input terminal in14 receives the third pulse Pulse13, and the second output terminal out 12 is connected to the gate of the first n-type transistor Q2. Moreover, the second inverting unit 412 outputs the second pulse Pulse12 in response to the third pulse Pulse13.

Please refer to FIG. 3(b), which shows a clamping circuit according to the third embodiment of the present invention. The clamping circuit 413 includes an amplifier 4131 and a second n-type transistor Q3. The amplifier 4131 has a positive input terminal in2+, a negative input terminal in2− and a third output terminal out13. The positive input terminal in2+ of the amplifier 4131 receives the first pulse Pulse11, and the negative input terminal in2− thereof receives the second voltage V_{c2}. Besides, the amplifier 4131 outputs a fourth pulse Pulse14 in response to the second voltage V_{c2} and the second pulse Pulse12. The gate of the second n-type transistor Q3 is connected to the third output terminal out13 and receives the fourth pulse Pulse14, and the drain thereof is connected to the positive input terminal in2+ of the amplifier 4131 and the gate of the first n-type transistor Q2. Moreover, the first n-type transistor Q2 adjusts the amplitude of the second pulse Pulse12 in response to the fourth pulse Pulse14.

Please refer to FIGS. 3(a) and 3(b) simultaneously. When the first voltage Vₒ₅ is increased, since the fourth voltage V_{FB2} is a divided voltage of the first voltage Vₒ₅, the fourth voltage V_{FB2} and the second voltage V_{c2} output by the operational amplifying unit 432 are changed accordingly, which enables the voltage input to the negative input terminal in2− of the amplifier 4131 in the clamping circuit 413 to be changed accordingly.

When the second n-type transistor Q3 is turned on, the voltage at the drain of the second n-type transistor Q3 is pulled down toward the ground potential (for example 0 V). Hence, the voltage input to the positive input terminal in2+ of the amplifier 4131 is decreased, until approaching the voltage at the negative input terminal in2− thereof (i.e. the second voltage V_{c2}). The voltage output from the third output terminal out13 of the amplifier 4131 can keep the second n-type transistor Q3 in a weak turn-on status. When the voltage at the drain of the second n-type transistor Q3 is pulled down toward the ground potential, the gate-to-source voltage V_{gs2} of the first n-type transistor Q2 is decreased. This can achieve the effect of clamping the voltage. Therefore, the first voltage Vₒ₅ is decreased. For the second pulse Pulse12, the magnitude of the amplitude thereof is increased toward 0 V so that the amplitude of the second pulse Pulse12 is adjusted. Similarly, when the first voltage Vₒ₅ is decreased, according to the principle similar to that described above, the effect of increasing the first voltage Vₒ₅ can be achieved. That is, the charge pump device 40 according to the third embodiment of the present invention can achieve the effect of regulating the first voltage Vₒ₅.

Please refer to FIG. 3(c), which shows the waveforms according to the third embodiment of the present invention. In the waveform diagram of the current i6, the transverse axle represents the time whose unit is the microsecond, and the vertical axle represents the current whose unit is the mill-ampere. In the waveform diagram of the first voltage Vₒ₅, the transverse axle represents the time whose unit is the microsecond, and the vertical axle represents the voltage whose unit is the volt. In the waveform diagram of the second pulse Pulse12, the transverse axle represents the time whose unit is the microsecond, and the vertical axle represents the voltage whose unit is the volt. In the waveform diagram of the first pulse Pulse11, the transverse axle represents the time whose unit is the microsecond, and the vertical axle represents the voltage whose unit is the volt.

Please refer to FIGS. 3(a), 3(b) and 3(c) simultaneously. When the current i6 is suddenly changed from 40 mA to about 8 mA, the first voltage Vₒ₅ is also suddenly changed from about −23.01 V to −23.07 V, which enables the amplitude of the fourth pulse Pulse14 to be reduced due to the adjustment by the clamping circuit 413. At this time, the amplitude of the second pulse Pulse12 is reduced due to the adjustment by the clamping circuit 313. Hence, the first voltage Vₒ₅ returns to −23.01 V soon.

Please refer to FIG. 3(d), which shows a clamping circuit according to a fourth embodiment of the present invention. The fourth embodiment of the present invention is similar to the third embodiment of the present invention, except the structure of the clamping circuit. The clamping circuit 413 in the third embodiment of the present invention can be replaced with the clamping circuit 415 in the fourth embodiment of the present invention. At this time, the operational amplifying unit 432 of FIG. 3(a) can be regarded as a trans-conductance unit 433. The trans-conductance unit 433 outputs a first current i7 in response to the fourth voltage V_{FB2}.

In FIG. 3(d), the second inverting unit 412 includes a second p-type transistor Q5 and a second n-type transistor Q6. The second inverting unit 412 has a fourth input terminal in15 and a second output terminal out14. The fourth input terminal in15 receives the third pulse Pulse13, and the second inverting unit 412 outputs the second pulse Pulse12 in response to the third pulse Pulse13. The second output terminal out14 is connected to the gate of the first n-type transistor Q2.

The clamping circuit 415 includes a third n-type transistor Q4 and a fourth n-type transistor Q7. The gate of the third n-type transistor Q4 is connected to the drain thereof. The third n-type transistor Q4 outputs a third voltage Vₒ₆ in response to the first current i7. The clamping circuit 415 further includes a transistor R₆ for converting the current i7 into the third voltage Vₒ₆. The gate of the fourth n-type transistor Q7 is connected to the gate of the third n-type transistor Q4, the drain of the fourth n-type transistor Q7 is connected to the drain of the second p-type transistor Q5, and the source of the fourth n-type transistor Q7 is connected to the drain of the second n-type transistor Q6 and the gate of the first n-type transistor Q2. The fourth n-type transistor Q7 adjusts the amplitude of the second pulse Pulse12 in response to the third voltage Vₒ₆.

Please refer to FIG. 3(e), which shows the waveforms according to the fourth embodiment of the present invention. In the waveform diagram of the currents i7, the transverse axle represents the time whose unit is the microsecond, and the vertical axle represents the current whose unit is the microampere. In the waveform diagram of the currents i6, the transverse axle represents the time whose unit is the microsecond, and the vertical axle represents the current whose unit is the milli-ampere. In the waveform diagram of the first voltage Vₒ₅, the transverse axle represents the time whose unit is the microsecond, and the vertical axle represents the voltage whose unit is the volt. In the waveform diagram of the first pulse Pulse11, the transverse axle represents the time whose unit is the microsecond, and the vertical axle represents the voltage whose unit is the volt. In the waveform diagram of the second pulse Pulse12, the transverse axle represents the time whose unit is the microsecond, and the vertical axle represents the voltage whose unit is the volt. In the waveform diagram of the fourth pulse Pulse14, the transverse axle represents the time whose unit is the microsecond, and the vertical axle represents the voltage whose unit is the volt.

Please refer to FIGS. 3(a), 3(d) and 3(e) simultaneously. When the current i6 is suddenly changed from 40 mA to about 8 mA, the first voltage Vₒ₅ is also suddenly changed from about −23.01 V to −23.07 V, and the current is changed from −9 uA to −7 uA. At this time, the amplitude of the fourth pulse Pulse14 is reduced due to the adjustment by the clamping circuit 415, and the amplitude of the second pulse Pulse12 is reduced due to the adjustment by the clamping circuit 415. Hence, the first voltage Vₒ₅ returns to −23.01 V soon.

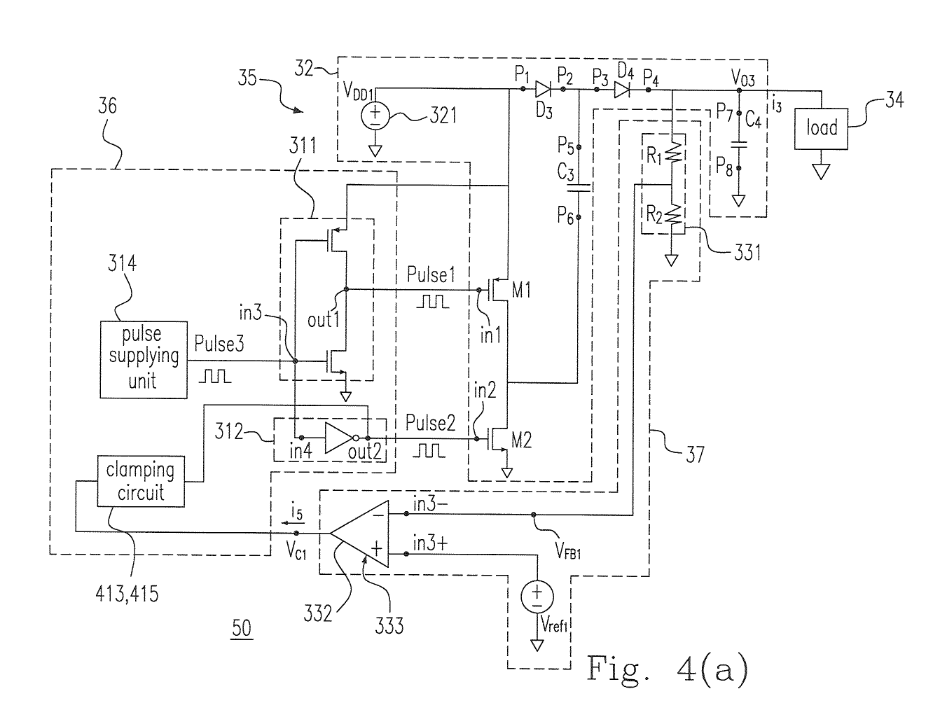

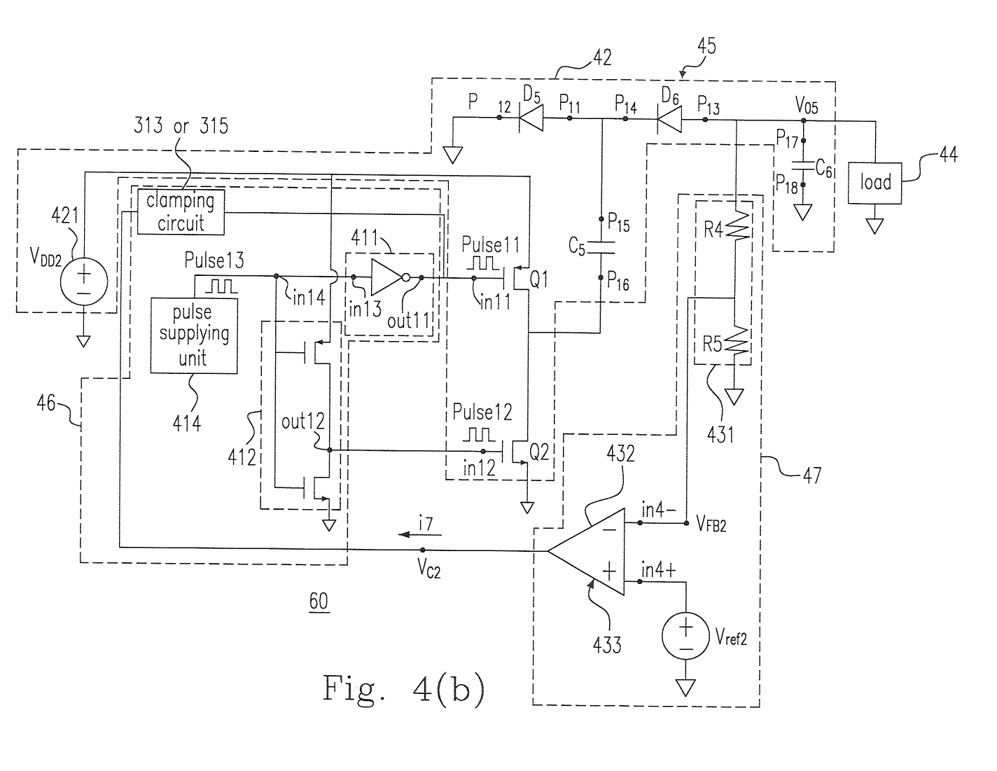

Please refer to FIG. 4(a), which shows a charge pump device according to a fifth embodiment of the present invention. The charge pump device 50 includes a clamping unit 36, a charge pump unit 32 and a feedback unit 37. The charge pump device 50 of FIG. 4(a) differs from the charge pump device 30 of FIG. 2(a) in that the clamping unit 31 is replaced with the clamping unit 36, and that the positive input terminal in3+ and the negative input terminal in3− of the operational amplifying unit 332 receive different voltages.

The clamping unit 36 differs from the clamping unit 31 in that the way of adjusting the amplitude of the first pulse Pulse1 by the clamping circuit 313 is changed into the way of adjusting the amplitude of the second pulse Pulse2 by the clamping circuit 413, or the way of adjusting the amplitude of the first pulse Pulse1 by the clamping circuit 315 is changed into the way of adjusting the amplitude of the second pulse Pulse2 by the clamping circuit 415.

In the embodiment of FIG. 4(a), the fourth voltage V_{FB1} is input to the negative input terminal in3− of the operational amplifying unit 332, and the reference voltage V_{ref1} is input to the positive input terminal in3+ thereof.

Please refer to FIG. 4(b), which shows a charge pump device according to a sixth embodiment of the present invention. The charge pump device 60 includes a clamping unit 46, a charge pump unit 45 and a feedback unit 47. The charge pump device 60 of FIG. 4(b) differs from the charge pump device 40 of FIG. 3(a) in that the clamping unit 41 is replaced with the clamping unit 46, and that the positive input terminal in3+ and the negative input terminal in3− of the operational amplifying unit 432 receive different voltages.

The clamping unit 46 differs from the clamping unit 41 in that the way of adjusting the amplitude of the second pulse Pulse12 by the clamping circuit 413 is changed into the way of adjusting the amplitude of the first pulse Pulse11 by the clamping circuit 313, or the way of adjusting the amplitude of the second pulse Pulse12 by the clamping circuit 415 is changed into the way of adjusting the amplitude of the first pulse Pulse11 by the clamping circuit 315.

In the embodiment of FIG. 4(b), the fourth voltage V_{FB2} is input to the negative input terminal in4− of the operational amplifying unit 432, and the reference voltage V_{ref2} is input to the positive input terminal in4+ thereof.

Based on the above, whether in the positive charge pump or in the negative charge pump, the clamping circuit 313 or 315 can be used in the clamping unit to adjust the amplitude of the first pulse Pulse1. Otherwise, the clamping circuit 413 or 415 can be added to the clamping unit simultaneously to adjust the amplitude of the first pulse Pulse1 and that of the second pulse Pulse2 at the same time. This also can achieve the effect of regulating the voltage.

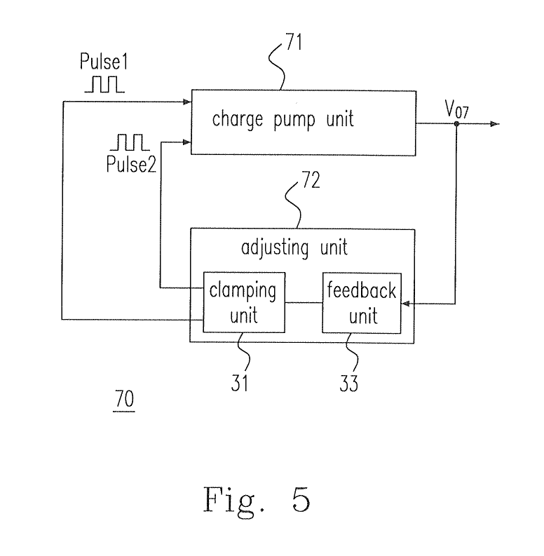

Please refer to FIG. 5, which shows a charge pump device according to a seventh embodiment of the present invention. The charge pump device 70 includes a charge pump unit 71 and an adjusting unit 72. The adjusting unit 72 includes the feedback unit 33 and the clamping unit 31. The charge pump unit 71 outputs a voltage Vₒ₇ in response to a first pulse Pulse1 and a second pulse Pulse2. When the voltage Vₒ₇ changes, the adjusting unit 72 adjusts the amplitude of the first pulse Pulse1 or the second pulse Pulse2 to regulate the voltage Vₒ₇.

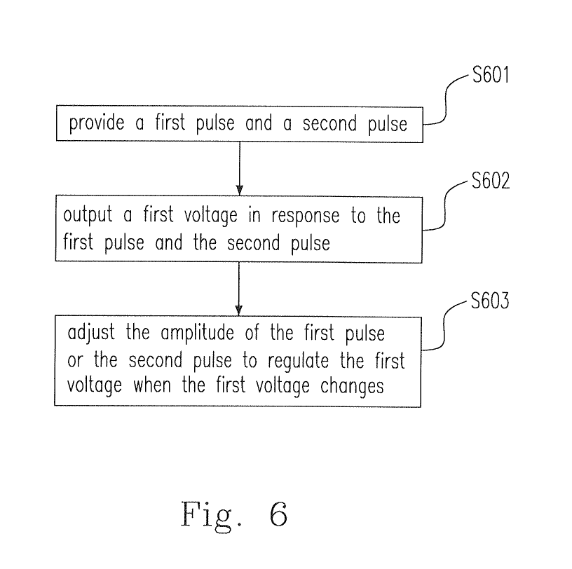

Please refer to FIG. 6, which is a flowchart of a method for regulating a charge pump device according to the present invention. In the step S601, a first pulse and a second pulse are provided. In the step S602, a first voltage is output in response to the first pulse and the second pulse. In the step S603, when the first voltage changes, the amplitude of the first pulse or the second pulse is adjusted to regulate the first voltage.

### Embodiments

1. A charge pump device, comprising:

a clamping unit providing a first pulse and a second pulse having a phase identical to that of the first pulse, wherein each of the first and the second pulses has an amplitude;

a charge pump unit outputting a first voltage in response to the first pulse and the second pulse; and

a feedback unit outputting a second voltage in response to the first voltage, wherein the clamping unit adjusts the amplitude of one of the first pulse and the second pulse in response to the second voltage to regulate the first voltage.

2. The charge pump device of Embodiment 1, wherein:

the charge pump unit has a first input terminal receiving the first pulse, and a second input terminal receiving the second pulse;

the charge pump unit is a positive charge pump unit comprising:
a DC voltage source providing a third voltage;
a first diode having a first terminal receiving the third voltage, and a second terminal;
a second diode having a third terminal connected to the second terminal, and a fourth terminal;
a first p-type transistor having a drain, a source receiving the third voltage, and a gate serving as the first input terminal;
a first n-type transistor having a source connected to a ground, a gate serving as the second input terminal, and a drain connected to the drain of the first p-type transistor;
a first capacitor having a fifth terminal connected to the third terminal, and a six terminal connected to the drain of the first p-type transistor; and
a second capacitor having a seventh terminal connected to the fourth terminal and a load of the charge pump device, and an eighth terminal connected to the ground; and

the feedback unit comprises:
a sensing unit including a voltage divider, wherein the voltage divider outputs a fourth voltage by dividing the first voltage; and
an operational amplifying unit receiving the fourth voltage and a reference voltage, and outputting the second voltage according to a difference between the fourth voltage and the reference voltage.
   3. The charge pump device of any one of Embodiments 1-2, wherein the clamping unit comprises:

a pulse supplying unit providing a third pulse;

a first inverting unit having a third input terminal receiving the third pulse, and a first output terminal connected to the gate of the first p-type transistor, wherein the first inverting unit outputs the first pulse in response to the third pulse;

a second inverting unit having a fourth input terminal receiving the third pulse, and a second output terminal connected to the gate of the first n-type transistor, wherein the second inverting unit outputs the second pulse in response to the third pulse; and

a clamping circuit including:
an amplifier having a positive input terminal receiving the first pulse, a negative input terminal receiving the second voltage, and a third output terminal, wherein the amplifier outputs a fourth pulse in response to the second voltage and the first pulse; and
a second p-type transistor having a gate connected to the third output terminal and receiving the fourth pulse, and a drain connected to the positive input terminal and the gate of the first p-type transistor, wherein the second p-type transistor adjusts the amplitude of the first pulse in response to the fourth pulse.
   4. The charge pump device of any one of Embodiments 1-3, wherein the clamping unit comprises:

a pulse supplying unit providing a third pulse;

a first inverting unit having a third input terminal receiving the third pulse, and a first output terminal connected to the gate of the first p-type transistor, wherein the first inverting unit outputs the first pulse in response to the third pulse;

a second inverting unit having a fourth input terminal receiving the third pulse, and a second output terminal connected to the gate of the first n-type transistor, wherein the second inverting unit outputs the second pulse in response to the third pulse; and

a clamping circuit including:
an amplifier having a positive input terminal receiving the second pulse, a negative input terminal receiving the second voltage, and a third output terminal, wherein the amplifier outputs a fourth pulse in response to the second voltage and the second pulse; and
a second n-type transistor having a gate connected to the third output terminal and receiving the fourth pulse, and a drain connected to the positive input terminal and the gate of the first n-type transistor, wherein the second n-type transistor adjusts the amplitude of the second pulse in response to the fourth pulse.
   5. The charge pump device of any one of Embodiments 1-4, wherein:

the charge pump unit has a first input terminal receiving the first pulse, and a second input terminal receiving the second pulse;

the charge pump unit is a negative charge pump unit comprising:
a DC voltage source providing a third voltage;
a first diode having a first terminal, and a second terminal connected to a ground;
a second diode having a third terminal, and a fourth terminal connected to the first terminal;
a first p-type transistor having a drain, a source receiving the third voltage, and a gate serving as the first input terminal;
a first n-type transistor having a source connected to the ground, a gate serving as the second input terminal, and a drain connected to the drain of the first p-type transistor;
a first capacitor having a fifth terminal connected to the fourth terminal, and a six terminal connected to the drain of the first p-type transistor; and
a second capacitor having a seventh terminal connected to the third terminal and a load of the charge pump device, and an eighth terminal connected to the ground; and

the feedback unit comprises:
a sensing unit including a voltage divider, wherein the voltage divider outputs a fourth voltage by dividing the first voltage; and
an operational amplifying unit receiving the fourth voltage and a reference voltage, and outputting the second voltage according to a difference between the fourth voltage and the reference voltage.
   6. The charge pump device of any one of Embodiments 1-5, wherein the clamping unit comprises:

a pulse supplying unit providing a third pulse;

a first inverting unit having a third input terminal receiving the third pulse, and a first output terminal connected to the gate of the first p-type transistor, wherein the first inverting unit outputs the first pulse in response to the third pulse;

a second inverting unit having a fourth input terminal receiving the third pulse, and a second output terminal connected to the gate of the first n-type transistor, wherein the second inverting unit outputs the second pulse in response to the third pulse; and

a clamping circuit including:
an amplifier having a positive input terminal receiving the second pulse, a negative input terminal receiving the second voltage, and a third output terminal, wherein the amplifier outputs a fourth pulse in response to the second voltage and the second pulse; and
a second n-type transistor having a gate connected to the third output terminal and receiving the fourth pulse, and a drain connected to the positive input terminal and the gate of the first n-type transistor, wherein the second n-type transistor adjusts the amplitude of the second pulse in response to the fourth pulse.
   7. The charge pump device of any one of Embodiments 1-6, wherein the clamping unit comprises:

a pulse supplying unit providing a third pulse;

a first inverting unit having a third input terminal receiving the third pulse, and a first output terminal connected to the gate of the first p-type transistor, wherein the first inverting unit outputs the first pulse in response to the third pulse;

a second inverting unit having a fourth input terminal receiving the third pulse, and a second output terminal connected to the gate of the first n-type transistor, wherein the second inverting unit outputs the second pulse in response to the third pulse; and

a clamping circuit including:
an amplifier having a positive input terminal receiving the first pulse, a negative input terminal receiving the second voltage, and a third output terminal, wherein the amplifier outputs a fourth pulse in response to the second voltage and the first pulse; and
a second p-type transistor having a gate connected to the third output terminal and receiving the fourth pulse, and a drain connected to the positive input terminal and the gate of the first p-type transistor, wherein the second p-type transistor adjusts the amplitude of the first pulse in response to the fourth pulse.
   8. A charge pump device, comprising:

a clamping unit providing a first pulse and a second pulse having a phase identical to that of the first pulse, wherein each of the first and the second pulses has an amplitude;

a charge pump unit outputting a first voltage in response to the first pulse and the second pulse; and

a feedback unit outputting a first current in response to the first voltage, wherein the clamping unit adjusts the amplitude of one of the first pulse and the second pulse in response to the first current to regulate the first voltage.

9. The charge pump device of Embodiment 8, wherein:

the charge pump unit has a first input terminal receiving the first pulse, and a second input terminal receiving the second pulse;

the charge pump unit is a positive charge pump unit comprising:
a DC voltage source providing a third voltage;
a first diode having a first terminal receiving the third voltage, and a second terminal;
a second diode having a third terminal connected to the second terminal, and a fourth terminal;
a first p-type transistor having a drain, a source receiving the third voltage, and a gate serving as the first input terminal;
a first n-type transistor having a source connected to a ground, a gate serving as the second input terminal, and a drain connected to the drain of the first p-type transistor;
a first capacitor having a fifth terminal connected to the third terminal, and a six terminal connected to the drain of the first p-type transistor; and
a second capacitor having a seventh terminal connected to the fourth terminal and a load of the charge pump device, and an eighth terminal connected to the ground; and

the feedback unit comprises:
a sensing unit including a voltage divider, wherein the voltage divider outputs a fourth voltage by dividing the first voltage; and
a trans-conductance unit receiving the fourth voltage and a reference voltage, and outputting the first current according to a difference between the fourth voltage and the reference voltage.
   10. The charge pump device of any one of Embodiments 8-9, wherein the clamping unit comprises:

a pulse supplying unit providing a third pulse;

a first inverting unit including a second p-type transistor and a second n-type transistor, and having a third input terminal receiving the third pulse and a first output terminal connected to the gate of the first p-type transistor, wherein the first inverting unit outputs the first pulse in response to the third pulse, and each of the second p-type transistor and the second n-type transistor has a drain;

a second inverting unit having a fourth input terminal receiving the third pulse, and a second output terminal connected to the gate of the first n-type transistor, wherein the second inverting unit outputs the second pulse in response to the third pulse; and

a clamping circuit including:
a third p-type transistor having a gate connected to a drain thereof, and outputting a third voltage in response to the first current; and
a fourth p-type transistor having a gate connected to the gate of the third p-type transistor, a drain connected to the drain of the second n-type transistor, and a source connected to the drain of the second p-type transistor and the gate of the first p-type transistor, wherein the fourth p-type transistor adjusts the amplitude of the first pulse in response to the third voltage.
   11. The charge pump device of any one of Embodiments 8-10, wherein the clamping unit comprises:

a pulse supplying unit providing a third pulse;

a first inverting unit having a third input terminal receiving the third pulse, and a first output terminal connected to the gate of the first p-type transistor, wherein the first inverting unit outputs the first pulse in response to the third pulse;

a second inverting unit including a second p-type transistor and a second n-type transistor, and having a fourth input terminal receiving the third pulse and a second output terminal connected to the gate of the first n-type transistor, wherein the second inverting unit outputs the second pulse in response to the third pulse, and each of the second p-type transistor and the second n-type transistor has a drain; and

a clamping circuit including:
a third n-type transistor having a gate connected to a drain thereof, and outputting a third voltage in response to the first current; and
a fourth n-type transistor having a gate connected to the gate of the third n-type transistor, a drain connected to the drain of the second p-type transistor, and a source connected to the drain of the second n-type transistor and the gate of the first n-type transistor, wherein the fourth n-type transistor adjusts an amplitude of the second pulse in response to the third voltage.
   12. A charge pump device, comprising:

a charge pump unit outputting a voltage in response to a first pulse and a second pulse, wherein each of the first and the second pulses has an amplitude; and

an adjusting unit adjusting the amplitude of one of the first pulse and the second pulse to regulate the voltage when the voltage changes.

13. A method for regulating a charge pump device, comprising steps of:

providing a first pulse and a second pulse, wherein each of the first and the second pulses has an amplitude;

outputting a first voltage in response to the first pulse and the second pulse; and

adjusting the amplitude of one of the first pulse and the second pulse to regulate the first voltage when the first voltage changes.

14. The method of Embodiment 13, further comprising steps of:

outputting a second voltage in response to a change of the first voltage; and

adjusting the amplitude of the first pulse in response to the second voltage and the first pulse.

15. The method of any one of Embodiments 13-14, further comprising steps of:

outputting a second voltage in response to a change of the first voltage; and

adjusting the amplitude of the second pulse in response to the second voltage and the second pulse.

16. The method of any one of Embodiments 13-15, further comprising steps of:

outputting a current in response to a change of the first voltage; and

adjusting the amplitude of one of the first pulse and the second pulse in response to the current.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A charge pump device, comprising:
a clamping unit providing a first pulse and a second pulse having a phase identical to that of the first pulse, wherein each of the first and the second pulses has an amplitude;
a charge pump unit outputting a first voltage in response to the first pulse and the second pulse; and
a feedback unit outputting a second voltage in response to the first voltage, wherein the clamping unit adjusts the amplitude of one of the first pulse and the second pulse in response to the second voltage to regulate the first voltage.

2. A charge pump device as claimed in claim 1, wherein:
the charge pump unit has a first input terminal receiving the first pulse, and a second input terminal receiving the second pulse;
the charge pump unit is a positive charge pump unit comprising:
a DC voltage source providing a third voltage;
a first diode having a first terminal receiving the third voltage, and a second terminal;
a second diode having a third terminal connected to the second terminal, and a fourth terminal;
a first p-type transistor having a drain, a source receiving the third voltage, and a gate serving as the first input terminal;
a first n-type transistor having a source connected to a ground, a gate serving as the second input terminal, and a drain connected to the drain of the first p-type transistor;
a first capacitor having a fifth terminal connected to the third terminal, and a six terminal connected to the drain of the first p-type transistor; and
a second capacitor having a seventh terminal connected to the fourth terminal and a load of the charge pump device, and an eighth terminal connected to the ground; and
the feedback unit comprises:
a sensing unit including a voltage divider, wherein the voltage divider outputs a fourth voltage by dividing the first voltage; and
an operational amplifying unit receiving the fourth voltage and a reference voltage, and outputting the second voltage according to a difference between the fourth voltage and the reference voltage.

3. A charge pump device as claimed in claim 2, wherein the clamping unit comprises:
a pulse supplying unit providing a third pulse;
a first inverting unit having a third input terminal receiving the third pulse, and a first output terminal connected to the gate of the first p-type transistor, wherein the first inverting unit outputs the first pulse in response to the third pulse;
a second inverting unit having a fourth input terminal receiving the third pulse, and a second output terminal connected to the gate of the first n-type transistor, wherein the second inverting unit outputs the second pulse in response to the third pulse; and
a clamping circuit including:
an amplifier having a positive input terminal receiving the first pulse, a negative input terminal receiving the second voltage, and a third output terminal, wherein the amplifier outputs a fourth pulse in response to the second voltage and the first pulse; and
a second p-type transistor having a gate connected to the third output terminal and receiving the fourth pulse, and a drain connected to the positive input terminal and the gate of the first p-type transistor, wherein the second p-type transistor adjusts the amplitude of the first pulse in response to the fourth pulse.

4. A charge pump device as claimed in claim 2, wherein the clamping unit comprises:
a pulse supplying unit providing a third pulse;
a first inverting unit having a third input terminal receiving the third pulse, and a first output terminal connected to the gate of the first p-type transistor, wherein the first inverting unit outputs the first pulse in response to the third pulse;
a second inverting unit having a fourth input terminal receiving the third pulse, and a second output terminal connected to the gate of the first n-type transistor, wherein the second inverting unit outputs the second pulse in response to the third pulse; and
a clamping circuit including:
an amplifier having a positive input terminal receiving the second pulse, a negative input terminal receiving the second voltage, and a third output terminal, wherein the amplifier outputs a fourth pulse in response to the second voltage and the second pulse; and
a second n-type transistor having a gate connected to the third output terminal and receiving the fourth pulse, and a drain connected to the positive input terminal and the gate of the first n-type transistor, wherein the second n-type transistor adjusts the amplitude of the second pulse in response to the fourth pulse.

5. A charge pump device as claimed in claim 1, wherein:
the charge pump unit has a first input terminal receiving the first pulse, and a second input terminal receiving the second pulse;
the charge pump unit is a negative charge pump unit comprising:
a DC voltage source providing a third voltage;
a first diode having a first terminal, and a second terminal connected to a ground;
a second diode having a third terminal, and a fourth terminal connected to the first terminal;
a first p-type transistor having a drain, a source receiving the third voltage, and a gate serving as the first input terminal;
a first n-type transistor having a source connected to the ground, a gate serving as the second input terminal, and a drain connected to the drain of the first p-type transistor;
a first capacitor having a fifth terminal connected to the fourth terminal, and a six terminal connected to the drain of the first p-type transistor; and
a second capacitor having a seventh terminal connected to the third terminal and a load of the charge pump device, and an eighth terminal connected to the ground; and
the feedback unit comprises:
a sensing unit including a voltage divider, wherein the voltage divider outputs a fourth voltage by dividing the first voltage; and
an operational amplifying unit receiving the fourth voltage and a reference voltage, and outputting the second voltage according to a difference between the fourth voltage and the reference voltage.

6. A charge pump device as claimed in claim 5, wherein the clamping unit comprises:
a pulse supplying unit providing a third pulse;
a first inverting unit having a third input terminal receiving the third pulse, and a first output terminal connected to the gate of the first p-type transistor, wherein the first inverting unit outputs the first pulse in response to the third pulse;
a second inverting unit having a fourth input terminal receiving the third pulse, and a second output terminal connected to the gate of the first n-type transistor, wherein the second inverting unit outputs the second pulse in response to the third pulse; and
a clamping circuit including:
an amplifier having a positive input terminal receiving the second pulse, a negative input terminal receiving the second voltage, and a third output terminal, wherein the amplifier outputs a fourth pulse in response to the second voltage and the second pulse; and
a second n-type transistor having a gate connected to the third output terminal and receiving the fourth pulse, and a drain connected to the positive input terminal and the gate of the first n-type transistor, wherein the second n-type transistor adjusts the amplitude of the second pulse in response to the fourth pulse.

7. A charge pump device as claimed in claim 5, wherein the clamping unit comprises:
a pulse supplying unit providing a third pulse;
a first inverting unit having a third input terminal receiving the third pulse, and a first output terminal connected to the gate of the first p-type transistor, wherein the first inverting unit outputs the first pulse in response to the third pulse;
a second inverting unit having a fourth input terminal receiving the third pulse, and a second output terminal connected to the gate of the first n-type transistor, wherein the second inverting unit outputs the second pulse in response to the third pulse; and
a clamping circuit including:
an amplifier having a positive input terminal receiving the first pulse, a negative input terminal receiving the second voltage, and a third output terminal, wherein the amplifier outputs a fourth pulse in response to the second voltage and the first pulse; and
a second p-type transistor having a gate connected to the third output terminal and receiving the fourth pulse, and a drain connected to the positive input terminal and the gate of the first p-type transistor, wherein the second p-type transistor adjusts the amplitude of the first pulse in response to the fourth pulse.

8. A charge pump device, comprising:
a clamping unit providing a first pulse and a second pulse having a phase identical to that of the first pulse, wherein each of the first and the second pulses has an amplitude;
a charge pump unit outputting a first voltage in response to the first pulse and the second pulse; and
a feedback unit outputting a first current in response to the first voltage, wherein the clamping unit adjusts the amplitude of one of the first pulse and the second pulse in response to the first current to regulate the first voltage.

9. A charge pump device as claimed in claim 8, wherein:
the charge pump unit has a first input terminal receiving the first pulse, and a second input terminal receiving the second pulse;
the charge pump unit is a positive charge pump unit comprising:
a DC voltage source providing a third voltage;
a first diode having a first terminal receiving the third voltage, and a second terminal;
a second diode having a third terminal connected to the second terminal, and a fourth terminal;
a first p-type transistor having a drain, a source receiving the third voltage, and a gate serving as the first input terminal;
a first n-type transistor having a source connected to a ground, a gate serving as the second input terminal, and a drain connected to the drain of the first p-type transistor;
a first capacitor having a fifth terminal connected to the third terminal, and a six terminal connected to the drain of the first p-type transistor; and
a second capacitor having a seventh terminal connected to the fourth terminal and a load of the charge pump device, and an eighth terminal connected to the ground; and
the feedback unit comprises:
a sensing unit including a voltage divider, wherein the voltage divider outputs a fourth voltage by dividing the first voltage; and
a trans-conductance unit receiving the fourth voltage and a reference voltage, and outputting the first current according to a difference between the fourth voltage and the reference voltage.

10. A charge pump device as claimed in claim 9, wherein the clamping unit comprises:
a pulse supplying unit providing a third pulse;
a first inverting unit including a second p-type transistor and a second n-type transistor, and having a third input terminal receiving the third pulse and a first output terminal connected to the gate of the first p-type transistor, wherein the first inverting unit outputs the first pulse in response to the third pulse, and each of the second p-type transistor and the second n-type transistor has a drain;
a second inverting unit having a fourth input terminal receiving the third pulse, and a second output terminal connected to the gate of the first n-type transistor, wherein the second inverting unit outputs the second pulse in response to the third pulse; and
a clamping circuit including:
a third p-type transistor having a gate connected to a drain thereof, and outputting a third voltage in response to the first current; and
a fourth p-type transistor having a gate connected to the gate of the third p-type transistor, a drain connected to the drain of the second n-type transistor, and a source connected to the drain of the second p-type transistor and the gate of the first p-type transistor, wherein the fourth p-type transistor adjusts the amplitude of the first pulse in response to the third voltage.

11. A charge pump device as claimed in claim 9, wherein the clamping unit comprises:
a pulse supplying unit providing a third pulse;
a first inverting unit having a third input terminal receiving the third pulse, and a first output terminal connected to the gate of the first p-type transistor, wherein the first inverting unit outputs the first pulse in response to the third pulse;
a second inverting unit including a second p-type transistor and a second n-type transistor, and having a fourth input terminal receiving the third pulse and a second output terminal connected to the gate of the first n-type transistor, wherein the second inverting unit outputs the second pulse in response to the third pulse, and each of the second p-type transistor and the second n-type transistor has a drain; and
a clamping circuit including:
a third n-type transistor having a gate connected to a drain thereof, and outputting a third voltage in response to the first current; and
a fourth n-type transistor having a gate connected to the gate of the third n-type transistor, a drain connected to the drain of the second p-type transistor, and a source connected to the drain of the second n-type transistor and the gate of the first n-type transistor, wherein the fourth n-type transistor adjusts an amplitude of the second pulse in response to the third voltage.

12. A charge pump device, comprising:
a charge pump unit outputting a voltage in response to a first pulse and a second pulse, wherein each of the first and the second pulses has an amplitude; and
an adjusting unit adjusting the amplitude of one of the first pulse and the second pulse to regulate the voltage when the voltage changes.

13. A method for regulating a charge pump device, comprising steps of: providing a first pulse and a second pulse, wherein each of the first and the second pulses has an amplitude;
outputting a first voltage in response to the first pulse and the second pulse; and
adjusting the amplitude of one of the first pulse and the second pulse to regulate the first voltage when the first voltage changes.

14. A method as claimed in claim 13, further comprising steps of:
outputting a second voltage in response to a change of the first voltage; and
adjusting the amplitude of the first pulse in response to the second voltage and the first pulse.

15. A method as claimed in claim 13, further comprising steps of:
outputting a second voltage in response to a change of the first voltage; and
adjusting the amplitude of the second pulse in response to the second voltage and the second pulse.

16. A method as claimed in claim 13, further comprising steps of:
outputting a current in response to a change of the first voltage; and
adjusting the amplitude of one of the first pulse and the second pulse in response to the current.
